(19) United States
(12) Patent Application Publication
(10) Pub. No.: US 2026/0043396 A1
(43) Pub. Date: Feb. 12, 2026

(54) High capacity hydrogen getter assemblies

(71) Applicants: Hua Xia, Huffman, TX (US); David Lee DeWire, Superior, CO (US)

(72) Inventors: Hua Xia, Huffman, TX (US); David Lee DeWire, Superior, CO (US)

(21) Appl. No.: 18/800,083

(22) Filed: Aug. 11, 2024

(51) Int. Cl. F04B 37/04; H05K 7/20

(52) U.S. Cl. CPC F04B 37/04; H05K 7/20136

(57) ABSTRACT

A hydrogen getter assembly designed to address significant hydrogen outgassing and scavenging challenges may incorporate a triple-layered structure created through plating techniques. In this setup, the middle layer is made of a highly reactive metal foil from rolling mills that absorbs hydrogen by forming hydrides, while the plated foil surfaces are tailored for hydrogen adsorption. The combination of electroless plating and pulsed electroplating processes facilitates rapid hydrogen diffusion from the nano-scale grain layers to the micro-scale grain gettering layer. This design effectively reduces the interface kinetic energy barrier and enhances the absorption rate, especially at low temperatures, without needing thermal activation or regeneration. The materials and structural design allow these getters to function over a broad temperature range, from as low as −162° C. in cryogenic conditions to elevated temperatures of 200-300° C., achieving hydrogen absorption capacities more than 100 times greater than current getters.

### FIELD OF THE INVENTION

The present invention pertains to high-capacity hydrogen getter assemblies, specifically to a hydrogen getter with a high absorption capacity that can effectively address various hydrogen outgassing and scavenging requirements, while operating reliably across a broad temperature range without the need for thermal activation or regeneration.

### BACKGROUND

Microelectronic packages, such as those used in microwave amplifiers, oscillators, and mixers, can experience reduced long-term reliability due to the emission of chemical contaminants, volatiles, and other substances from the packaging materials. These emissions, which include hydrogen, moisture, organics, and hydrocarbons, originate from the materials within the packaging. Typically, these hermetically sealed microelectronic assemblies contain semiconductor devices made from materials like gallium arsenide (GaAs), indium phosphide (InP), and gallium nitride (GaN), all of which are sensitive to hydrogen outgassing. Once the package is sealed, hydrogen can accumulate within the package headspace, potentially leading to significant changes in operating parameters such as voltage, frequency, leakage current, corrosion, loss of electrical insulation, and impaired thermal dissipation.

Hydrogen outgassing in small quantities can occur from various microelectronic components and packaging materials, including Ni/Au plated housings, plated lids, polymers, epoxies, adhesives, gap fillers, RF absorbers, and printed circuit boards (PCBs). Even in controlled environments with low hydrogen levels, devices are susceptible to gradual outgassing from these materials. Over time, and with repeated thermal cycling, these contaminant gases can accumulate within the sealed package headspace. Hermetically sealed microelectronic devices may release hydrogen in varying amounts: 1% by volume (10,000 ppmv) for low-outgassing packages, 3-5% by volume (30,000-50,000 ppmv) for medium-outgassing packages, and 5-10% by volume (50,000-100,000 ppmv) for high-outgassing packages over the device's lifespan. Given that the volume of these packages ranges from 0.1 cubic centimeters (cc) to 100 cc, the corresponding hydrogen gas volume can range from 0.01 cc to 10 cc, with a potential total outgassing of 10 cc of outgassed hydrogen over 10-20 years of operation.

High-quantity hydrogen outgassing occurs in various industrial electronics systems. For example, in lead-acid batteries, hydrogen gas is generated during overcharging, which splits water (H₂O) into hydrogen (H₂) and oxygen (O₂) gases and leads to pressure build-up within the battery; and in oil and gas downhole electronics, materials and components outgas hydrogen due to the high temperatures and pressures encountered in drilling and well-logging equipment. Similarly, hydrogen is generated from the radiolysis of water and other materials in nuclear power vessels. High-quantity hydrogen outgassing can also occur in MRI and imaging equipment, high-power cooling systems of supercomputers, spacecraft and aerospace electronics control systems, and polymer material-based packages; all of which are subject to extreme temperature and pressure variations, as well as thermal stress loading cycles. The outgassed hydrogen in these systems can exceed 100 cc or reach to 1000 cc. Many other industrial electronics systems and semi-hermetic polymer electronic packages also experience significant hydrogen outgassing, necessitating rapid hydrogen scavenging to ensure long-term operational reliability under diverse temperature and pressure conditions.

Getter technologies, based on polymers, metals, and composites, have been developed to remove outgassed hydrogen from various enclosures and packages. Microelectronic packages, typically sealed in vacuum or inert gas environments, must operate at temperatures ranging from −55° C. to 125-150° C., as specified by MIL-STD-833. Getters aim to reduce hydrogen concentrations to below 100 ppmv for GaAs and InP microwave devices and below 1000 ppmv for other electronics packages. Ideally, the getter should provide sufficient hydrogen absorption capacity to effectively scavenge any outgassed H2 from a package. These getters include polymer-based getters with carbon-carbon double bonds doped with palladium catalysts, zeolite/PdO particles embedded in silicone polymer matrices, metal getters with palladium foil, Pd-coated Ti film on a Kovar substrate, and non-evaporable zirconium-metal composite getters. These technologies can effectively scavenge outgassed hydrogen from various hermetically sealed microelectronic and optoelectronic packages with volumes of less than 1 cc, as well as electronics packages with volumes of up to a few hundred cc.

However, these getters have limitations in hydrogen absorption capacity and operating temperature range, which complicates their use in managing high-quantity hydrogen outgassing in industrial settings, particularly under fluctuating temperatures and thermal cycling. For instance, polymer-based getters have a low adsorption capacity of less than 35 torr-liter/g, or approximately 10 cc for a getter with 25.4×25.4×0.25 mm³ size, and are effective only at ambient temperatures or below 100° C. due to high desorption rates above 50° C. In applications where there is a significant amount of outgassing, such as large electronic enclosures or industrial systems, polymer getters may not have the capacity to absorb all the outgassed hydrogen and other gases. For systems that need to operate reliably over long periods polymer getters might not provide sufficient long-term stability and capacity, especially at high-temperature environments. In high vacuum systems, the outgassing rates can be very high, and polymer getters might not be able to maintain the required low pressure levels. For sensitive electronic components that require very low levels of contaminants, polymer getters might not be able to achieve the necessary purity levels.

Hydrogen reactive metal materials, such as palladium and titanium, have been used for gettering material. Pd-based hydrogen getters offer higher capacities, such as 100 cc for a 25.4×25.4×0.15 mm³ foil, but the high cost of palladium (around $30,000/kg) makes thick getter foils impractical. Pd-coated titanium on a Kovar substrate provides better absorption capacity than Pd-based getters, but its effectiveness is limited by film thickness, constrained to 1-5 μm due to the thermal expansion mismatch (α_Kovar=5.1 ppm/° C., α_Ti=8.6 ppm/° C.) induced thermal interface stress under elevated temperatures. To maintain reliable adhesion and minimize interface stress, titanium films on Kovar substrates are generally limited to 1-2 micrometers (μm) under normal conditions. For applications with thermal cycling or extreme temperatures, thinner films (less than 1 μm) are preferred to reduce stress and enhance reliability. Although titanium films have high hydrogen absorption capabilities, their total absorption capacity cannot be significantly increased due to reliability required thin film thickness and associated interface stress management for maintaining its reliability for long-term operation under thermal loading cycles.

Furthermore, Zirconium (Zr)-metal-based hydrogen getters are widely used in applications ranging from electronics packages to vacuum systems due to their effective hydrogen absorption capabilities. However, Zr-metal getters require activation or regeneration at high temperatures, typically above 300° C. This process often involves heating the getter in a vacuum to remove previously adsorbed hydrogen and restore its capacity. Many electronic packages operate at temperatures below this threshold, making it impractical to activate or regenerate the getters without exceeding the safe operating temperature. The high activation temperature also means that Zr-metal getters are generally unsuitable for applications with maximum operating temperatures below 125-150° C. This restricts their use in electronic packages and other applications where lower temperatures are prevalent. Even after activation, the lifetime of Zr-metal getters can be limited by the cumulative exposure to hydrogen and other environmental factors. This can necessitate replacement or regeneration of the getters over time, impacting maintenance schedules and operational reliability. Moreover, integrating Zr-metal based composite getter with embedded electric heating wires for activation and regeneration in an electronics package is problematic, as the use of electricity for heating the getter could spark fires in oxygen-rich environments. Furthermore, existing getters with low capacity are also unsuitable for polymer-based electronics packages, whether hermetically sealed or near-hermetically sealed.

Given these constraints, it is desirable to develop getters as thin films or foils that do not require activation and regeneration at elevated temperatures or vacuum conditions. Additionally, these getters should offer high to extra-high capacity to effectively address hydrogen outgassing and scavenging challenges in small-volume microelectronic packages, medium-sized electronic packages, and large industrial electronics systems and semi-hermetic polymer electronic packages. Therefore, there is a need for developing a hydrogen getter with a high absorption capacity that can meet various hydrogen outgassing and scavenging needs and operate reliably over a wide temperature range without requiring thermal activation and regeneration.

### SUMMARY OF THE INVENTION

The terms “invention,” “the invention,” “this invention,” and “present invention” refer to all subject matter described in this disclosure and the claims. Similarly, the terms “plated layer,” “layer,” “thin film,” and “coating layer” are used interchangeably. The terms “getter,” “getter element,” and “getter assembly” are also interchangeable. Additionally, “microelectronics package” or “microelectronic package” and “electronics package” or “electronic packages” are used interchangeably. Statements containing these terms should not be construed to limit the subject matter described herein or the meaning or scope of the claims. The embodiments of the invention are defined by the claims and not by this summary, which provides a high-level overview of various aspects of the invention and introduces concepts that are elaborated on in the Detailed Description section below. This summary is not intended to identify key, required, or essential features of the claimed subject matter, nor is it intended to be used in isolation to determine the scope of the claimed subject matter. The subject matter should be understood by referring to the entire specification of this patent, including any drawings and each claim.

Embodiments of the invention relate to a structure or assembly designed as a hydrogen gas getter, providing a solution to the hydrogen scavenging challenge associated with high outgassing from various packaging materials used in hermetically sealed microelectronics and electronics packages, and industrial electronics systems. In some embodiments, the inventive structure features a triple-layered assembly, with the middle layer comprising a highly reactive Ti metal foil for hydrogen absorption by forming TiH2 hydrides, and the top and bottom layers, based on Pd metal, designed for high hydrogen adsorption and permeation. Specifically, the middle layer may consist of rolling mill titanium foil with micrometer-scale grain boundaries, while the top and bottom Pd layers have nano-scale grain boundaries. Hydrogen atoms are effectively diffused from the nano-scale Pd layer to the micro-scale grain Ti boundary interface, driven by hydrogen concentration gradients and reduced kinetic energy barriers. These embodiments enable the production of high-capacity hydrogen getter assemblies that do not require activation or regeneration.

In another aspect, embodiments of the invention involve a structure or assembly used as a hydrogen gas getter, addressing hydrogen scavenging issues due to high outgassing from packaging materials in hermetically sealed microelectronics and electronics packages. Some embodiments include a substrate-supported bilayer structure, where the middle layer, adjacent to substrate, is a plated hydrogen-reactive Ti metal film, and the top or outer layer, based on Pd metal, is designed for high hydrogen adsorption and permeation. The middle layer may be a Ti film with micrometer-scale grain boundaries, while the top or outer layer features nano-scale grain boundaries. Hydrogen atoms diffuse from the nano-scale Pd layer to the micro-scale grain Ti layer boundary interface influenced by concentration gradients and reduced kinetic energy barriers. The substrate could be an electrically conductive metal or a dielectric ceramic or glass. This structure allows for the production of high-capacity hydrogen getter assemblies that do not require activation or regeneration.

Further embodiments of the invention involve methods for manufacturing a hydrogen getter assembly. Some methods include electroless plating to create a triple-layered getter assembly with a thin Pd hydrogen-adsorptive layer surrounding a hydrogen-reactive Ti metal foil. Other methods may involve pulse-mode electroplating to apply a hydrogen-reactive titanium layer onto an electrically conductive substrate, followed by plating a hydrogen-adsorptive Pd layer with nano-scale grain morphology. Additional methods may involve plating a hydrogen-reactive titanium layer, a few micrometers thick, with electroless plating on a dielectric substrate, then using pulse-mode electroplating to apply a titanium layer ranging from 0.1 mm to a few 1.0 mm in thickness, followed by plating a hydrogen-adsorptive Pd layer with nano-scale grain morphology. Combining plating methods with pulsed mode operation allows for precise control over material microstructures and morphologies, optimizing grain boundary interfaces to reduce kinetic energy barriers and enhance absorption rates at low temperatures. These methods further enable the production of high-capacity hydrogen getter assemblies with reliable performance across a wide range of operating temperatures.

In one aspect, the disclosed embodiment directed to hydrogen getter assembly is a triple-layered structure, where a hydrogen reactive gettering layer sandwiched between gas adsorption layers. Pd is selected for the gas adsorption layer in the getter assembly to adsorb hydrogen from the package headspace. The gettering layer is a rolling mill Ti foil with oxide-removed surfaces. The gas adsorption layer has a first coefficient of thermal expansion (α_1), Poisson's ratio (v_1), and Young's modulus (E_1); the getter layer has a second coefficient of thermal expansion (α_2), Poisson's ratio (v_2), and Young's modulus (E_2). The getter assembly consists of a Ti gettering layer sandwiched between two Pd gas adsorption layers, fabricated by electroless plating or electroplating methods. The thermal stress in the first gas adsorption layer and the gettering layer are described by:

$$σ\_ 1 ( T ) = E\_ 1 \cdot ( α\_ 1 - α\_ 2 ) \cdot ( T - T\_ ( o ) , ) \qquad ( 1 )$$

$$σ\_ 2 ( T ) = E\_ 2 \cdot ( α\_ 2 - α\_ 1 ) \cdot ( T - T\_ ( o ) , ) \qquad ( 2 )$$

Depending on the materials' properties, the first layer may be in tensile stress while the second layer could be in compressive stress. If a third layer is plated onto layer 2, a sandwiched triple-layer structure is created with symmetrically balanced stress:

$$σ\_ 3 ( T ) = E\_ 1 \cdot ( α\_ 1 - α\_ 2 ) \cdot ( T - T\_ ( o ) , ) = σ\_ 1 \qquad ( 3 )$$

This thermally stress-balanced structure effectively reduces interface stress, enhancing interface adhesion strength and mitigating issues such as film buckling, cracks, and other reliability concerns, which disclose the physics in enabling a getter assembly operable under extreme temperature range, such as from cryogenic −162° C. to elevated 300° C.

In further aspect, the disclosed embodiments focus on the hydrogen absorption capacity of the getter assembly. The gettering layer in the stress-symmetrically balanced assembly utilizes rolling mill Ti foil, which can form multiple hydrides, with titanium dihydride (TiH₂) being the most common. In this structure, the hydrogen-to-metal atomic ratio (H/Ti) is 2, corresponding to a hydrogen storage capacity of approximately 4% by weight. In comparison, Pd can absorb hydrogen to an atomic ratio (H/Pd) of about 0.6 to 0.7 under standard conditions. The higher hydride formation capacity of TiH₂ compared to PdH (0.6-0.7) highlights the advanced capabilities of the getter assembly to achieve high hydrogen absorption capacity.

In further embodiments, a Pd layer with nano-scale grain, 20-50 nm, boundaries is plated onto a rolling mill Ti foil with micrometer-scale grain, 5-20 μm, boundaries. The nano-scale grain boundaries in the Pd layer create numerous high-diffusivity pathways and more active sites for hydrogen adsorption, facilitating faster hydrogen uptake. The larger grain boundaries in the rolling mill Ti foil accommodate more hydrogen atoms, resulting in a higher overall hydrogen absorption capacity compared to finer grains. Although the interface between the nano-scale Pd grains and the micrometer-scale Ti grains might present a size mismatch, this can benefit hydrogen diffusion. The dense grain boundaries in the nano-scale Pd layer provide multiple entry points for hydrogen atoms, which can then diffuse into the Ti layer, where the micrometer-scale boundaries further aid their movement. This combination of rapid diffusion in the nano-scale Pd layer and substantial absorption capacity in the micrometer-scale Ti layer enhances the hydrogen absorption rate, even at extremely low temperatures. Additionally, a thin Pd layer serves as anti-oxidation protection, preventing the gettering layer from interacting with outgassed oxygen, while providing selectivity and permeability for hydrogen and inhibiting the permeation of other gases.

According to another embodiment consistent with the principles of the invention, a Pd-plated Ti-based hydrogen getter assembly does not require a regeneration process. The Ti layer can form TiH₂ with a high hydrogen-to-metal atomic ratio, allowing it to absorb significant amounts of hydrogen. A rolling mill foil up to a few millimeters thick can absorb several thousand to tens of thousands of cubic centimeters of hydrogen. This large absorption capacity reduces the likelihood of saturation during the operational lifespan, eliminating the need for periodic regeneration. The titanium hydrides in the Ti layer are stable and do not easily release hydrogen under typical operating conditions, ensuring that the absorbed hydrogen remains securely trapped. The Pd plating facilitates rapid hydrogen diffusion into the Ti layer, enabling continuous and effective scavenging without the need for regeneration. Designed to operate effectively across a broad temperature range—from cryogenic (−162° C.) to elevated temperatures (up to 300° C.)—the getter maintains its functionality over time without performance degradation or the need for regeneration, due mainly to high absorption provided by TiH2 hydride formation.

According to another embodiment consistent with the principles of the invention, the disclosed embodiments relate to the activation of the getter assemblies. A Pd-coated Ti-based thin film hydrogen getter does not require activation due to the inherent reactivity of Ti with hydrogen, which allows it to readily form titanium hydrides (TiH₂) at relatively low temperatures. This high reactivity enables the Ti layer to absorb hydrogen directly from the environment without additional activation energy. The Pd coating acts as a catalyst, with its high affinity for hydrogen facilitating the adsorption and dissociation of hydrogen molecules into atomic hydrogen. These hydrogen atoms can then diffuse rapidly through the Pd layer and into the Ti layer, negating the need for activation. Nano-scale grain boundaries in the Pd layer create numerous high-diffusivity pathways for hydrogen, enhancing the absorption rate and eliminating the need for pre-activation. The combination of nano-scale Pd grains and micro-scale Ti grains further reduces the activation energy required for hydrogen diffusion. Grain boundaries and defects in both layers act as preferential sites for hydrogen absorption and hydride formation, ensuring effective gettering even at ambient or low temperatures. This continuous hydrogen absorption capability means that the getter does not require a separate activation step.

This summary provides an overview of several getter designs and materials used, without limitation. Further details of the present disclosure will be appreciated by reviewing the entire document, accompanying figures, and claims.

### BRIEF DESCRIPTION OF THE DRAWINGS

Aspects of the present disclosure are best understood from the following detailed description when read with the accompanying figures. But these descriptions and drawings are illustrative and are not to be construed as limiting. Numerous specific details are described to provide a thorough understanding of the disclosure. However, in certain instances, well-known details are not described in order to avoid obscuring the description. Further, various getter design modifications may be made without deviating from the scope of the embodiments. The invention will be further illustrated with the help of the following figures where:

FIG. 1 illustrates cross-sectional views of a hydrogen getter assembly comprising gettering layer sandwiched between two gas adsorption layers, with a symmetric thermal and interface stress around middle gettering layer, according to embodiments of the invention;

FIG. 2 illustrates cross-sectional views of a hydrogen getter assembly comprising gas adsorption layer and gettering layer co-plated onto a substrate, according to embodiments of the invention;

FIG. 3 illustrates a flow diagram of fabrication method for making getter assemblies by thin film plating methods, according to embodiments of the invention;

FIG. 4 displays the interface stress amplitudes from cryogenic temperatures to an elevated temperature of 400° C. for a 0.50 mm-Ti gettering layer, sandwiched between 5 μm-Pd gas adsorption layers, as described herein;

FIG. 5 illustrates the maximum allowed shear strength of 25 MPa determined operating temperature dependence upon the gettering layer thickness for a Ti gettering layer sandwiched between 5 μm-Pd gas adsorption layers, as described herein;

FIG. 6 illustrates the maximum allowed shear strength of 25 MPa determined operating temperature dependence upon the gettering layer thickness for a 5 μm-Pd/Ti co-plated 0.25 mm-thick electrically conductive Kovar foil assembly, as described in the present invention;

FIG. 7 illustrates the maximum allowed shear strength of 10 MPa determined operating temperature dependence upon the gettering layer thickness for a 5 μm-Pd/Ti co-plated 0.125 mm-thick electrically insulating Alumina substrate assembly, as described in the present invention;

FIG. 8 illustrates the outgassed hydrogen in volume, cubic centimeter (cc), versus outgassed hydrogen in parts per million by volume, where 1 cc package corresponds to small microelectronic devices or modules, while 100 cc package may represent most of electronics packages or enclosures. The outgassed hydrogen in percentage reflects total outgassing amount from a package during 10-20 years operation, as described herein;

FIG. 9 illustrates the outgassed hydrogen, in cubic centimeter (cc), versus package volume, under total outgassed hydrogen in percentage for 20 years' operation; and the comparison with a typical getter assembly, as disclosed herein;

FIG. 10 illustrates the high capacity H2 getter (H2G), in cubic centimeter (cc), from different getter assemblies, operating from −55° C. to 125-150° C. range. For solving hydrogen outgassing and scavenging issues, a thickness of 7.5-15 μm in gettering layer could handle 10-20 cc outgassed hydrogen removal for most microelectronics devices, modules, and packages, as labeled by H2G10 and H2G20. A thickness of 70 μm in gettering layer could handle 100 cc outgassed hydrogen removal for most electronics devices, modules, and packages, as labeled by H2G100. Furthermore, a thickness of 300-700 μm in gettering layer could handle 500-1000 cc outgassed hydrogen removal for most industrial electronics packages and enclosures, as labeled by H2G500 and H2G1000. The “X” stands for getter assemblies can operate from cryogenic temperature −162° C. to elevated temperatures of 200-300° C., as disclosed herein;

FIG. 11 illustrates cross-sectional views of getter assembly installation onto a package lid surface, or interior wall, even at any locations close to some components with higher H2 outgassing, by heat spot welding method;

FIG. 12 illustrates cross-sectional views of getter assembly installation onto a package lid surface by low-outgassing adhesive method, disclosed herein, and

FIG. 13 illustrates getter assembly installation onto a package by mounting it onto printed circuit board with a Pin Grid Array (PGA) or Land Grid Array (LGA) socket, or/and with a IC socket method, as described herein.

### DETAILED DESCRIPTION OF INVENTION

The embodiments described in this disclosure are illustrative and not intended to be limiting. The disclosed embodiments represent specific examples, but various alternative forms and materials can be employed. Therefore, the detailed structural and functional aspects described should be viewed as a guide for those skilled in the art to adapt and apply the principles of the present disclosure. It is understood that features shown in any figure can be combined with those from other figures to create embodiments that may not be explicitly detailed. Various modifications and combinations of features consistent with the teachings of this disclosure may be adapted for particular applications or implementations.

The primary objective of the invention is to provide hydrogen getter assemblies with high absorptivity, permeability, and capacity to remove outgassed hydrogen from packages, such as microelectronics devices, electronics enclosures, or industrial electronics systems. This disclosure focuses on high-capacity hydrogen getter assemblies comprising nano-structured gas adsorption materials and micro-structured gettering materials. These assemblies are created using a combination of electroless plating and electroplating techniques, achieving hydrogen capacities exceeding 15 torr-liters/cm² and operational temperatures ranging from −162° C. to 240-300° C. For instance, a hydrogen getter assembly with a 0.25 mm-thick gettering layer can achieve a capacity of 44 torr-liters/cm² and a 2.54 mm-thick gettering layer can achieve a capacity of 444 torr-liters/cm², with its operating temperature ranging from −55° C. to 125-150° C.

One embodiment features a getter assembly with a gettering layer and two gas adsorption layers, creating a symmetric triple-layer structure. Alternatively, another embodiment involves plating a gettering layer onto a substrate, followed by a gas adsorption layer to form a bilayer structure supported by the substrate. The gettering layer can be made from various materials with hydrogen absorption capabilities, including platinum, palladium, titanium, barium, rare earth elements, and nickel. Titanium, in particular, is effective due to its ability to form multiple hydrides, with titanium dihydride (TiH₂) being the most common. This form has a hydrogen-to-metal atomic ratio (H/Ti) of 2, providing a hydrogen storage capacity of about 4% by weight. In contrast, palladium absorbs hydrogen to an atomic ratio (H/Pd) of approximately 0.6 to 0.7 under standard conditions. Given TiH₂'s superior hydride formation capacity compared to PdH (0.6-0.7), titanium is favored for its higher absorption capacity.

When using titanium as the gettering layer, its sensitivity to oxygen must be considered, as oxygen can degrade performance over time by forming oxides. To protect titanium and maintain its high adsorption capacity, a protective layer can be added. This protective layer can include metals or metal alloys such as pure palladium, palladium-nickel, palladium-silver, palladium-gold alloys, or combinations thereof, with concentrations of nickel, silver, or gold ranging from 1 wt. % to 15 wt. %. Thin palladium is preferred for the gas adsorption layer due to its superior hydrogen selectivity, permeability, and affinity, which help preserve the gettering layer's integrity and enhance its gas adsorption capabilities.

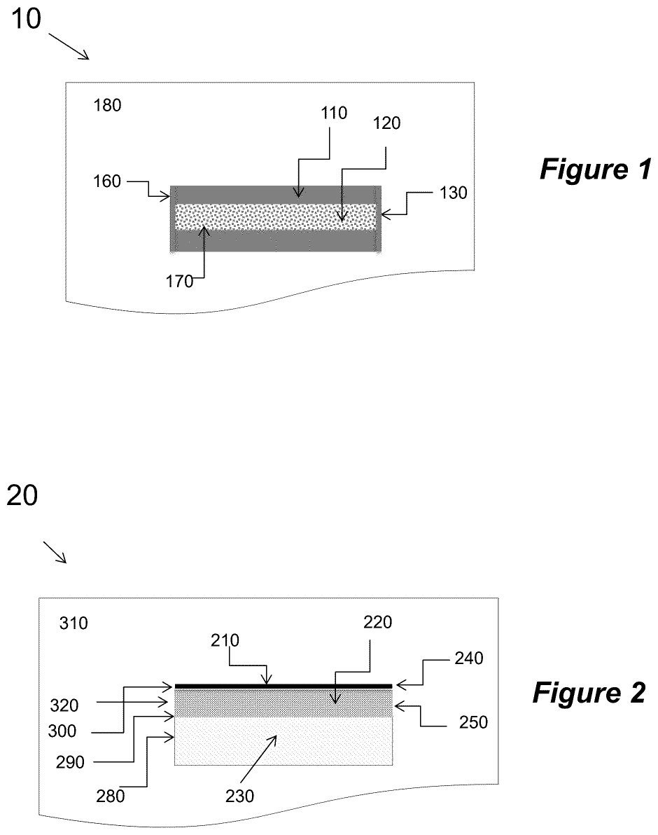

FIG. 1 depicts a getter assembly fabricated using an electroless plating method to coat a gettering layer 120 with a gas adsorption material. The cross-sectional view illustrates the getter assembly 10, which includes the gas adsorption layer 110, gettering layer 120, the gettering layer's thickness 130, thickness of the gas adsorption layer 160, the interface 170 between the gas adsorption layer and the gettering layer, and the package headspace 180. The getter assembly 10 may be a component within an electronic package, mounted on electronic components, or on the internal surfaces of a package or hermetic lid. The gas adsorption layer 110 adsorbs hydrogen from the package headspace 180, which is the small volume of air or inert gas remaining after sealing, potentially containing contaminants or outgassed gases. Hydrogen adsorbed by the gas adsorption layer 110 dissociates into atoms, which then diffuse across interface 170 into the gettering layer 120. The dimensions of the gettering layer 120 include its thickness 130 and size, while the gas adsorption layer 110 has a thickness of 160.

FIG. 2 shows a getter assembly 20 created using both electroless plating and electroplating techniques to coat a gettering layer 220 with a gas adsorption material 210 on a substrate 230. The cross-sectional view displays the getter assembly 20, which comprises the gas adsorption layer 210, gettering layer 220, substrate 230, and the dimensions: thickness of the gettering layer 240, thickness of the substrate 280, interface 290 between the gettering layer and the substrate, interface 300 between the gas adsorption layer 210 and the gettering layer 220, and the headspace of the package 310. This getter assembly 20 can be a small component in an electronic package, attached to electronic components, the interior walls of the package, or the internal surface of a hermetic lid. The gas adsorption layer 210 adsorbs hydrogen released from the package headspace 310 and is plated onto the gettering layer 220. Hydrogen from the gas adsorption layer 210 dissociates into atoms that diffuse across interface 300 into the gettering layer 220. The gettering layer 220 is characterized by its thickness 250, while the gas adsorption layer has a thickness of 240. Additionally, the gettering layer may have lateral edges 320. The substrate 230 provides mechanical support for the gettering layer 220, with interface 290 ensuring a stable connection.

Both getter assemblies 10 and 20 include a gas adsorption layer 110, 210 and a gettering layer 120, 220. The gas adsorption layer 110, 210 is made of palladium material. In some embodiments, this layer features nanostructures with nano-scale grain morphology. The gettering layer 120, 220 consists of titanium metal foil, which can be pure titanium or grades 2, 4, or 5, depending on the mechanical strength requirements. Titanium's effectiveness in hydrogen scavenging is enhanced by its ability to form multiple hydrides, particularly TiH₂, with a hydrogen-to-metal atomic ratio (H/Ti) of 2. In comparison, palladium has a lower absorption ratio (H/Pd) of about 0.6 to 0.7. The choice of titanium grade—whether pure, grade 2, or grade 4—depends on the specific mechanical strength needs of the getter assembly. Grade 5 titanium (Ti-6Al-4V) is used when biocompatibility is a concern, such as in medical implantable devices.

The interfaces 170 in assembly 10 and 300 in assembly 20 are metal-to-metal interfaces formed during the plating process of titanium foil with a thin palladium layer. These interfaces exhibit strong atomic bonding with minimal voids and defects. The nano-scale gas adsorption layers 110, 210 have distinct grain structures compared to the gettering layer 120, 220, and the grain boundaries at these interfaces can act as diffusion pathways, facilitating gas movement. In one embodiment, these grain boundaries are designed to enhance the hydrogen adsorption rate. In another embodiment, transitioning from nano-scale to micrometer-scale grains lowers the energy barrier, improving hydrogen gas absorption, especially at cryogenic temperatures. To further increase the gas absorption rate, the gas adsorption layer 110, 210 is kept thin to minimize obstacles and allow hydrogen atoms to diffuse more readily into the gettering layer 120, 220.

The substrate 230 in getter assembly 20 can be made of glass, metal, ceramic, or thermoplastic polymer. Metals are beneficial due to their high thermal conductivity, which helps distribute heat evenly across the substrate, making them suitable for applications where heat dissipation is crucial. Metals also provide strong mechanical support, enhancing stability and durability. Dielectric substrates offer electrical insulation, important for preventing electrical interference and ensuring system integrity. In some embodiments, the substrate 230 primarily provides mechanical support for the gettering layer 220, while in others; an electrically conductive substrate 230 enhances gas sorption rate and thermal management. Dielectric substrates can also offer electromagnetic interference shielding, and electrically insulated polymers like PEEK and PTFE provide flexible mechanical support and EMI shielding.

To apply a gettering material and gas adsorption material to a substrate 230, electroless plating can produce a layer thickness of a few micrometers to about 10 micrometers, regardless of whether the substrate is conductive or insulating. Electroplating can achieve thicknesses of 50-100 micrometers but is limited to electrically conductive substrates. Combining these methods allows for creating a gettering layer up to 100 micrometers thick through electroplating on a conductive substrate. Thicker layers may require increased plating time, which can lead to stress buildup, reduced uniformity, and potential cracking. An alternative approach is to apply multiple layers of plating, allowing each to cool before adding the next, although this might cause oxidation of the Ti gettering layer 120, 220 surfaces. The preferred method involves pulse plating, where the current is periodically turned on and off or reversed, to precisely control the deposition process, enhance microstructure, and reduce internal stresses, allowing for potentially thicker layers.

For dielectric substrates 230, the preferred approach involves first using electroless plating to metallize the surface, then applying electroplating to deposit a thicker gettering layer 120, 220. The gettering layer 120, 220 can then be coated using one of the plating methods. In one embodiment, the thicker gettering layer 120, 220 is created with electroplating under pulse mode. In another embodiment, a thin gas adsorption layer is applied using either electroless or electroplating techniques. Additionally, in some embodiments, electroless plating is used initially to metallize the dielectric substrate, followed by electroplating under pulse mode to produce a thicker gettering layer, and then a gas adsorption layer is added using one of the plating methods.

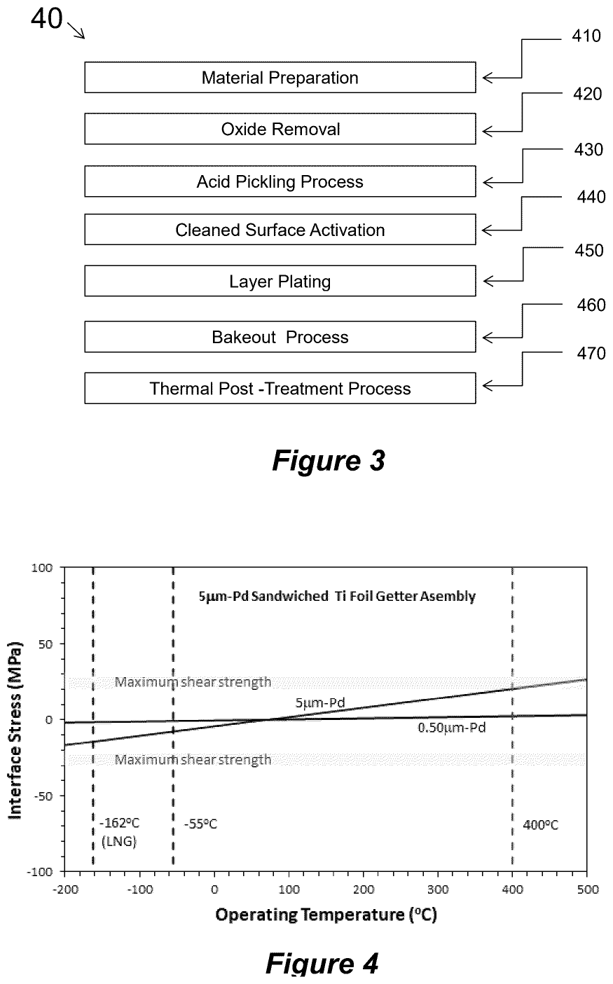

FIG. 3 depicts a flowchart outlining the fabrication of a getter assembly using electroless and electroplating methods according to the present disclosure. The method (40) includes seven steps: material preparation (410), oxide removal (420), acid pickling (430), surface activation (440), layer plating (450), a bakeout process (460), and a thermal post-treatment process (470). These steps are standard practices for producing a high-quality getter assembly, but the invention is not limited to these specific steps.

Step 410 involves cleaning the gettering material foil with an alkaline cleaner or degreaser to remove oils, greases, and other contaminants, followed by a thorough rinse with deionized water.

Step 420 involves making an acid etching solution for metal surface oxide layer removal. It includes using a dilute solution of hydrofluoric acid (HF) or a mixture of hydrochloric acid (HCl) and nitric acid (HNO₃). A specific etching solution may be prepared with 10% HF, 30% HNO₃, and 60% water.

Step 430 relates to acid pickling that involves submerging the titanium foil in the etching solution, allowing it to soak from several minutes to an hour to remove the oxide layer, and then thoroughly rinsing it with clean water.

Step 440 surface activation includes dipping the cleaned titanium foil in a sensitizing solution containing stannous chloride (SnCl₂) for 1-2 minutes, followed by immersion in an activation solution containing palladium chloride (PdCl₂) for 1-2 minutes, and then thoroughly rinsing with deionized water.

Step 450 involves preparing plating bath at a temperature of 50° C. to 70° C. and adjusting the bath pH to 8-10. However, the preferred bath temperature is close to getter assembly operating temperature for reducing interface stress around getter operating temperature. The plating may be operated under pulsed mode to obtain high-quality plating layers.

Step 460 is a bakeout process that heats the plated getter assemblies to a temperature of 150° C.-200° C. for 1-4 hours to outgas hydrogen with a vacuum furnace. The higher the bakeout temperature the shorter the dwell time is.

Step 470 involves a thermal post-treatment process in which the getter assembly is annealed at temperatures ranging from 200° C. to 400° C. for duration from a few hours to 48 hours. This process relieves interface stresses, enhances ductility, condenses the surface to reduce pinholes, and improves bond strength at the interface. However, in an oxygen-rich environment, this treatment can oxidize the freshly cut gettering material, forming TiO₂ thin films that act as a barrier to outgas permeation into the gettering layer.

The layer plating may be preferred in pulse electroplating mode for producing high-quality titanium films with fine-grain structures. In pulse electroplating, the current or voltage is applied in short bursts or pulses rather than continuously. This pulsed mode allows for better control over the deposition process, leading to more uniform and fine-grained titanium films. Short on-times help in reducing the instantaneous current density, minimizing issues like roughness or uneven deposition. The period when the current is turned off allows the electrolyte to refresh near the substrate surface and relaxes the concentration gradients. This reduces the risk of stress buildup and enhances the nucleation of new grains, promoting finer grain structures. Higher frequencies with shorter on-off cycles tend to produce finer grains by promoting rapid nucleation and limiting excessive growth of individual grains. A lower duty cycle (ratio of on-time to the total cycle time) often results in smoother films with refined grains by providing ample time for ion redistribution and stress relaxation. Pulse plating encourages multiple nucleation sites to form during each pulse, leading to smaller and more uniform grain sizes. The off-time allows for stress relaxation, which is critical in preventing defects like cracks or delamination in the deposited layer. The controlled deposition rates minimize the formation of large grains or columnar structures, resulting in a smooth, fine-grained film.

Table 1 is predicted efficiency of a getter in terms of outgas adsorption and permeation, based on theoretical analyses from the used gas adsorption material Pd, and gas gettering material, Ti foil. Adsorption isotherms depict how gases adhere to a solid surface at a constant temperature, while permeation theory examines how gases diffuse through and are absorbed by materials. The overall permeability efficiency is generally predicted by multiplying the diffusion coefficient by the solubility coefficient of the gas within the getter material. Factors such as temperature, pressure, and the presence of other gases can affect both adsorption and permeation. Table 1 specifically presents the qualitative efficiencies for various emitted gases. The Pd-based gas adsorption layer exhibits high hydrogen permeability for titanium, resulting in hydride formation. However, outgassed oxygen, carbon monoxide, and carbon dioxide show low to medium adsorption efficiency with very limited permeability. Hydrocarbons and volatile organic compounds demonstrate negligible permeability and reactivity. The absence of interference from other gases ensures that the designed getters are specifically effective at scavenging hydrogen.

TABLE 1
Outgasses and their adsorption efficiency and permeability
analyses from the high capacity hydrogen getter assemblies.

| Outgas from | Predicted | |
|---|---|---|
| package | efficiency | Rational |
| Hydrogen (H₂) | Very high | High permeability Pd for H2, |
| | | and Ti forms hydrides |
| Carbon oxide (CO) | Low to | Limited Pd permeability, surface |
| Carbon dioxide (CO₂) | medium | adsorption on gas adsorption |
| Oxygen (O₂) | | layer surface only |
| Nitrogen (N₂) | Low | Very limited reactivity and |
| Hydrocarbons (HCs) | | permeability |
| Volatile Organic | | Limited Pd permeability and |
| Compounds (VOCs) | | reactivity |

When Pd is coated onto a Ti foil, hydrogen atoms can form PdH hydrides within the Pd layer but still diffuse through this layer to reach the underlying Ti. Despite the formation of PdH hydride, hydrogen atoms remain mobile within the Pd lattice due to its relatively high hydrogen solubility and diffusivity. The formation of PdH hydride does not block hydrogen from reaching the Ti layer, as long as there is a concentration gradient and available sites for hydrogen in the Ti layer. Once hydrogen atoms arrive at the Ti layer, they can form TiH₂ hydride, which has a higher hydrogen absorption capacity. The strong affinity of Ti for hydrogen promotes the formation of TiH₂. Although PdH formation in the Pd layer may slightly slow down hydrogen diffusion, it does not prevent it. The Pd layer serves as both a reservoir and mediator, enabling continuous hydrogen diffusion into the Ti layer, where TiH₂ hydride can form.

In one embodiment, a Pd layer with nano-scaled grain boundaries is plated onto a rolling mill Ti layer with micrometer-scale grain boundaries. The nano-scaled grain boundaries in the Pd layer provide numerous high-diffusivity pathways for hydrogen atoms. The smaller grain size increases the surface area-to-volume ratio, offering more active sites for hydrogen adsorption and facilitating faster hydrogen uptake. Meanwhile, the micrometer-scale grain boundaries in the rolling mill Ti layer offer ample space for TiH₂ hydride formation. These boundaries serve as preferential sites for hydrogen diffusion and hydride nucleation. The larger grain boundaries in the rolling mill Ti foil can hold more hydrogen atoms, leading to a higher overall hydrogen absorption capacity compared to finer grains. Although there is a grain size mismatch between the nano-scaled Pd grains and the micrometer-scale Ti grains, this actually benefits hydrogen diffusion. The dense grain boundaries in the nano-scaled Pd layer create multiple entry points for hydrogen atoms. Once these atoms reach the interface, they can diffuse into the Ti layer, where the micrometer-scale boundaries continue to aid their movement. The combination of rapid diffusion through the nano-grain boundaries of Pd and the significant absorption capacity in the micro-grain boundaries of Ti results in an increased hydrogen absorption rate, demonstrating the effective absorption rate even at extremely low temperatures.

Getter assemblies are generally designed to function within a specified temperature range, such as −55° C. to 125° C., as outlined by MIL-STD-833, to ensure reliable performance for 10-20 years across various environments. However, these assemblies may fail under extreme conditions, such as cryogenic temperatures (−162° C.) or severe thermal cycling. Although the materials in a getter element may be capable of withstanding a wider temperature range, the overall reliability is affected not only by the materials themselves but also by thermal interface stresses resulting from mismatched thermal expansions. Different materials have different coefficients of thermal expansion (CTEs), causing differential expansion or contraction with temperature changes and leading to thermal stresses at the interfaces. The degree of mismatch and resulting interface stress in the getter assembly can be quantified using the formula:

$$α ( T ) = E\_ 1 \cdot ( α\_ 1 - α\_ 2 ) \cdot ( T - T\_o ) \cdot ( E\_ 1 \cdot h\_ 1 ) / ( E\_ 1 \cdot h\_ 1 + ( 1 - v\_ 1 ) \cdot E\_ 2 \cdot h\_ 2 ) \qquad ( 4 )$$

where E_1 and E_2 is the Young's modulus from two different materials, v is the Poisson's ratio, α_1 and α_2 are the CTEs of the two materials, h_1 and h_2 are the thicknesses of the layers, and T_o is the plating bath temperature. High thermal interface stress can result in weak bonding interfaces or delamination during high thermal loading cycles. The maximum shear stress criterion is often used to evaluate the severity of thermal stress in getters, helping to determine the onset of material yielding or failure, particularly at extreme temperatures (<−55° C. or >125° C.). For metal-to-metal and metal-to-dielectric interfaces the maximum shear strengths are normally less than 25 MPa and 10 MPa, respectively.

FIG. 4 displays the calculated thermal interface stress for a 0.50 mm thick Ti gettering layer sandwiched between 5 μm-thick Pd gas adsorption layers, across an operating temperature range from −200° C. to 400° C. The stress at the interface between a 0.5 μm-thick Pd gas adsorption layer and the 0.50 mm thick Ti foil is minimal and largely unaffected by temperature changes. However, as the thickness of the Pd layer increases, the interface stress also rises. For a 0.50 mm thick Ti foil sandwiched between 5 μm-thick Pd layers, the stress reaches its peak shear strength of 25 MPa around 420° C. At lower temperatures, including cryogenic temperatures of −162° C. (typical for LNG), the thermal stress remains well below the maximum shear strength of ˜25 MPa.

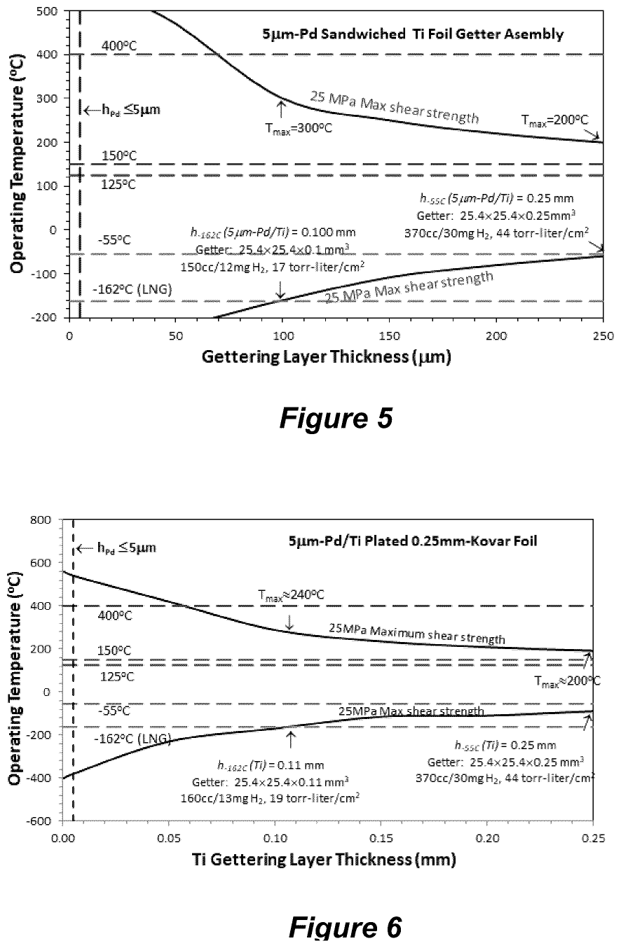

FIG. 5 illustrates the operating temperature range as a function of gettering layer thickness, based on a maximum allowable shear strength of 25 MPa for a 0.50 mm thick Ti foil sandwiched between 5 μm-thick Pd gas adsorption layers. Two specific getter designs are detailed. The first design uses a 0.10 mm thick Ti layer between the Pd layers, allowing reliable operation from −162° C. (LNG temperature) to 300° C. while keeping interface thermal stress below the maximum shear strength of ˜25 MPa. The second design incorporates a 0.25 mm thick Ti layer between Pd layers, suitable for operation from −55° C. to 200° C. within acceptable thermal stress limits. The first design, with a 25.4×25.4×0.10 mm³ size, has a hydrogen absorption capacity of 17 torr-liter/cm², while the second design, with the same dimensions but a thickness of 0.25 mm, offers 44 torr-liter/cm².

FIG. 5 has disclosed that a getter assembly with a Ti foil sandwiched between Pd gas desorption layers creates a structure where thermal stresses induced by temperature changes are evenly distributed around the central layer. This symmetrical design ensures balanced thermal expansion and contraction, significantly reducing the likelihood of bending or warping of the assembly. The uniform thermal expansion on both sides also results in lower shear stress at the interfaces, minimizing the risk of delamination caused by differential thermal expansion. This is particularly beneficial in high-power electronic applications where effective heat management is crucial. The symmetrical structure of the getter assembly enhances mechanical and thermal stability, reducing the risk of structural failures across a wide temperature range, from cryogenic temperatures of −162° C. to elevated temperatures of 300° C.

FIG. 6 presents the operating temperature range as a function of gettering layer thickness, based on the maximum allowable shear strength of ˜25 MPa for a 5 μm-thick Pd/Ti plated electrically conductive Kovar foil of 0.25 mm thickness. Two specific getter designs are illustrated. The first design features a 0.11 mm thick Ti layer, enabling reliable operation from −162° C. (LNG temperature) to 240° C. while keeping interface thermal stress below 25 MPa. The second design includes a 5 μm-thick Pd layer and a 0.25 mm thick Ti layer co-plated onto electrically conductive Kovar foil, suitable for operation from −55° C. to 200° C. within acceptable thermal stress limits. The first design, with a 25.4×25.4×0.011 mm³, has a hydrogen absorption capacity of 19 torr-liter/cm², while the second design, with the same dimensions but a thickness of 2.5 mm, offers 44 torr-liter/cm². Both designs can absorb 13 mg and 30 mg of outgassed hydrogen, respectively, from an electronics package. Increasing the thickness of the gettering layer enhances absorption capacity for a given size, providing flexible design options for higher capacities.

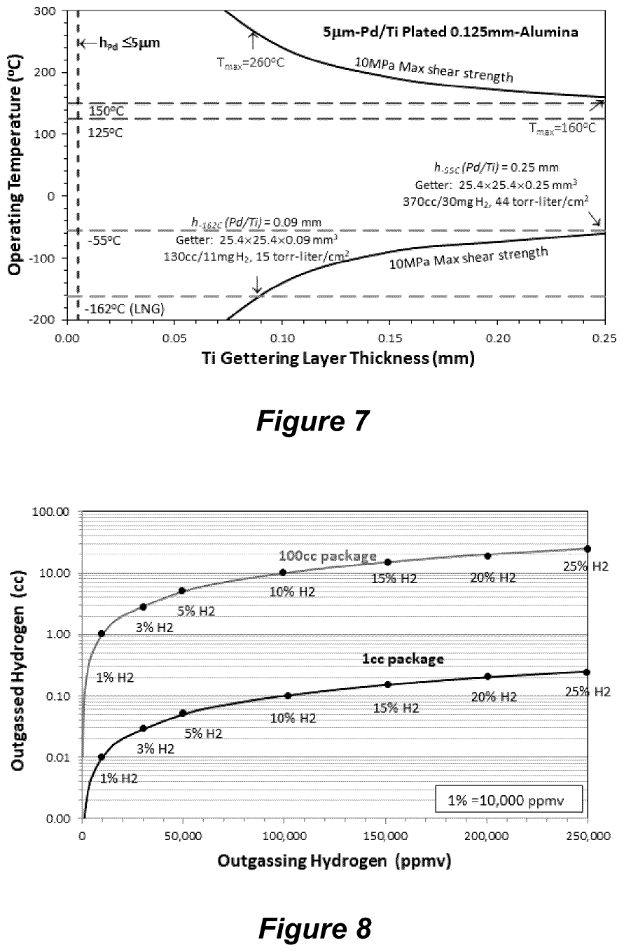

FIG. 7 shows the operating temperature range as a function of gettering layer thickness, based on the maximum allowable shear strength of ˜10 MPa for a 5 μm-thick Pd/Ti plated electrically insulated alumina substrate of 0.125 mm thickness. Two specific getter designs are described. The first design has a 0.09 mm thick Ti layer, allowing operation from −162° C. (LNG temperature) to 260° C., while maintaining interface thermal stress below 10 MPa due to the metal-to-ceramic interface. The second design features a 5 μm-thick Pd layer and a 0.25 mm thick Ti layer co-plated onto an electrically insulated alumina substrate, suitable for operation from −55° C. to 160° C. within acceptable thermal stress limits. The first design, with a 25.4×25.4×0.09 mm³, has a hydrogen absorption capacity of 15 torr-liter/cm², while the second design, with the same dimensions but a thickness of 0.25 cm, offers 44 torr-liter/cm².

Increasing the thickness of the gettering layer improves the absorption capacity for a given length and width, offering flexible design options for higher capacity getters. Low-capacity getters (15 torr-liter/cm²) are ideal for small microelectronic devices and modules. Medium-capacity getters (30 torr-liter/cm²) are suitable for electronic packages, while high-capacity getters (100 torr-liter/cm²) are appropriate for various industrial electronics systems and semi-hermetic polymer electronic packages. These high-capacity getters offer significantly absorption capabilities compared to polymer moisture/hydrogen getters (˜1 torr-liter/cm²), which is more suited for applications with limited hydrogen exposure, and to Pd-based hydrogen getters (10 torr-liter/cm²).

The operating profiles in FIG. 5, FIG. 6, and FIG. 7 are based on the maximum shear strength between different materials. For metal-to-metal interfaces, the maximum shear strength is approximately 25 MPa, while it is around 10 MPa for metal-to-dielectric material interfaces. The discrepancy in shear strength arises from the differences in bonding nature and material properties. Metal-to-metal interfaces are typically characterized by metallic bonds, which are strong and flexible, allowing for some plastic deformation and higher shear strength (25-30 MPa). In contrast, ceramics and glasses have ionic or covalent bonds, which are stronger but more brittle. At metal-to-ceramic or metal-to-glass interfaces, the bonding involves mechanical interlocking, van der Waals forces, and weaker chemical bonds, making them less able to accommodate plastic deformation and leading to lower shear strength (10-20 MPa).

The determination of a getter's absorption capacity is based on analyzing the outgassed hydrogen from a device or package relative to its specific volume. Small packages (0.1 cc to 1 cc) include microelectronics devices, sensors, MEMS, and compact modules. Medium packages (1 cc to 100 cc) encompass larger integrated circuits, power modules, communication modules, and more complex devices. Large packages (100 cc to around 500 cc) cover large electronic assemblies, lead acid batteries, power electronics, high-performance computing modules, and other sizable supercomputer and other electronics enclosures. Hydrogen gas is outgassed from various components and packaging materials, including Ni/Au plated housings, Kovar lids, polymers, epoxies, adhesives, gap fillers, RF absorbers, and PCBs. Even in controlled environments with low hydrogen levels, gradual outgassing from these materials can increase contaminant gas concentrations within the sealed package. Hermetically sealed devices can outgas 1% (10,000 ppmv) hydrogen in low-outgassing packages, 3-5% (30,000-50,000 ppmv) in medium outgassing packages, and up to 5-10% (50,000-100,000 ppmv) in high outgassing polymer packages over their lifespan.

Packaging materials can theoretically release varying amounts of gases into the package headspace, leading to concentrations like 5-10% by package volume. The actual outgassing levels are influenced by factors such as the materials used, environmental conditions, and the duration over which outgassing occurs. Polymers and plastics, especially those that are not fully cured or stabilized, can emit significant amounts of residual solvents, plasticizers, and monomers. Higher temperatures can accelerate this process by increasing the vapor pressure of volatile compounds. While outgassing typically decreases over time as the most volatile components are released first, materials with long-term outgassing characteristics can continue to release hydrogen and other gases at lower rates throughout the device's lifespan. A concentration of 1% by volume (10,000 ppmv) might be seen in packages with moderately outgassing materials, such as some plastics, especially in smaller enclosed volumes. A 5% by volume (50,000 ppmv) outgassing might occur in packages with less controlled materials or those with higher surface-area-to-volume ratios. Extreme cases, such as 5-10% by volume outgassing, are rare but can happen in polymer packages with highly volatile organic materials, poorly controlled processes, or under high temperatures.

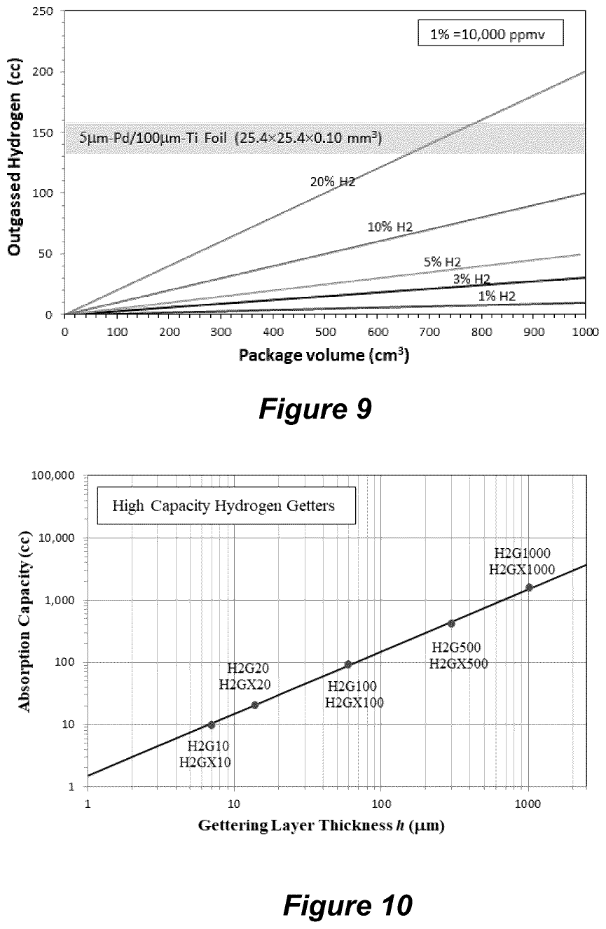

FIG. 8 shows a calculation converting hydrogen concentration (ppmv) in a package into the total volume of hydrogen gas in cubic centimeters (cc). For a package with a volume of 1 cc, a hydrogen concentration of 10% by volume (100,000 ppmv) translates to approximately 0.1 cc of hydrogen gas. If the package volume is increased to 10 cc, the hydrogen gas volume would be around 1 cc. In extreme outgassing scenarios at 10% by volume, the hydrogen gas volume would be about 0.1 cc for a 1 cc package volume, and 1 cc for a 10 cc package volume. FIG. 9 assesses the volume of outgassed hydrogen across different package sizes, from small to 1000 cc. The analysis shows that the volume of outgassed hydrogen is directly proportional to the package volume, assuming a constant total amount of outgassed hydrogen. For a total outgassed hydrogen concentration of around 10% by volume, a 500 cc package could accumulate up to 50 cc of hydrogen over a 10-20 year operational lifetime.

To address this outgassed hydrogen; various polymer-based hydrogen getters can offer capacities of 5-7 cc, assuming a typical getter size of 25.4□25.4□0.25 mm³. This capacity is insufficient for larger volumes. In contrast, a Pd-based getter can provide up to 110 cc capacity, with a typical size of 25.4□25.4□0.15 mm³, offering a safety factor of 2.2. A getter assembly with a 100 μm-thick Ti foil sandwiched between 5 μm-thick Pd gas adsorption layers can achieve capacities of 130 cc (FIG. 7), 150 cc (FIG. 5), and 160 cc (FIG. 6), with safety factors of 2.6, 3.0, and 3.2, respectively. These assemblies can operate over a broad temperature range, from −162° C. (cryogenic temperatures) to elevated temperatures of 240° C., 260° C., and 300° C., respectively.

FIG. 10 demonstrates the capacity of high capacity H2 getters (HC-H2G) in cubic centimeters (cc) for various gettering layer thicknesses, sandwiched between 5 μm Pd layers, where “HC” represents high capacity. For hydrogen outgassing and scavenging, a getter with a 7-15 μm thick gettering layer can handle 10-20 cc of outgassed hydrogen for most microelectronics devices, modules, and packages (labeled H2G10, H2GX10, H2G20, H2GX20), A 70 μm thick gettering layer can manage 100 cc of outgassed hydrogen for most electronics devices, modules, and packages (labeled H2G100, H2GX100). A 300 μm thick gettering layer can handle 500 cc of outgassed hydrogen for most electronics packages (labeled as H2G500 and H2GX500). Additionally, a 1-mm thick gettering layer can manage over 1000 cc of outgassed hydrogen, making it suitable for industrial electronics packages and enclosures (labeled as H2G1000 and H2GX1000). The standard getter assemblies models can be specified to have a nominal operating range from −55° C. to 125-150° C. while other models will be distinguished by “X” standing for extended operating temperature ranging from −162° C. to >200-300° C. Increasing the getter layer thickness does not significantly impact effort or cost, allowing the hydrogen absorption capacity of the getter assemblies to exceed 1000 cc for a 25.4×25.4×1.0 mm³ getter, making regeneration unlikely during its operational lifetime. For practical applications, a getter with a 0.1 mm or 100 μm thick gettering layers can handle 150 cc of outgassed hydrogen for most microelectronics devices, modules, and packages, and is unlikely to be saturated by outgassing from packages with volumes less than 100 cc. However, the high capacity of greater than 500 cc from this invention could provide desirable solutions for handling hydrogen-related reliability and safety issues in large fuel cells, lead-acid batteries, supercomputer cooling systems, nuclear boiling water reactor vessels, and many enclosed electronics systems in petrochemical, refinery, oil/gas, and energy production facilities, where the existing getters has no practical use because of low capacity, narrow operating temperature and dedicate getter material degradation due to harsh high temperature, pressure, and mechanical and thermal loading cycles.

Selecting a getter with adequate absorption capacity is essential for effective hydrogen gas removal. Determining the maximum outgassing quantity from a package over its lifetime is challenging. To ensure that the getter can accommodate unexpected variations in outgassing rates or quantities, safety factors are used. One approach is to consider an absorption capacity safety factor, which is the ratio of the getter's actual gas absorption capacity to the estimated total amount of gas that will be released over the product's lifetime. A safety factor of 2 to 3 is typically preferred, accounting for uncertainties in gas generation rates and variations in material outgassing. Alternatively, it is recommended that the getter's absorption rate be at least twice the maximum expected gas generation rate to ensure effective absorption during peak outgassing events. Additionally, a temperature range safety factor of 1.5 is preferred, ensuring that the getter remains effective over a temperature range broader by one-third than the expected operating conditions, accommodating temperature fluctuations and thermal spikes.

It is important to note that a getter typically achieves around 80% of its theoretical maximum capacity under ambient conditions, with an unabsorbed portion ranging from 5% to 20%, depending on specific conditions and design safety margins. The inability of a getter to reach its maximum capacity is influenced by the kinetics and thermodynamics of gas absorption and the overall effectiveness of the getter material. At lower temperatures, reduced kinetic energy of gas molecules slows adsorption and absorption rates, potentially preventing the getter from reaching its maximum capacity within the desired timeframe. Some getters require thermal activation to absorb gases efficiently, and if the operating temperature is below this activation threshold, the getter may not fully activate, leading to reduced capacity. For low-outgassing devices, modules, and packages operating between −162° C. and 300° C., a safety factor of 10-30 is recommended. For medium-outgassing devices operating at temperatures below-55° C. or above 125° C., a safety factor of 30-60 is preferred. For high-outgassing devices operating at temperatures below −55° C. or above 125° C., a safety factor of 60-100 is suggested.

Ensuring mechanical reliability in a getter assembly requires managing thermal stresses between the gettering layer and gas adsorption layers. A thinner Pd layer is preferred to minimize the impact of thermal expansion differences across a wide temperature range. This approach also reduces potential delamination issues between the Pd and Ti layers, ensuring reliable performance throughout the temperature range. Although Pd's hydrogen absorption capacity decreases at cryogenic temperatures due to lower kinetic energy and slower diffusion rates, it still absorbs hydrogen, albeit more slowly. A thin Pd-plated Ti foil getter assembly provides excellent hydrogen absorption performance across a broad temperature range, from cryogenic temperatures to 300° C. In one embodiment, the preferred thickness of the Pd-based gas adsorption layer ranges from 0.1 μm to 0.5 μm. In another embodiment, a thickness ranging from 0.5 μm to 5 μm is preferred.

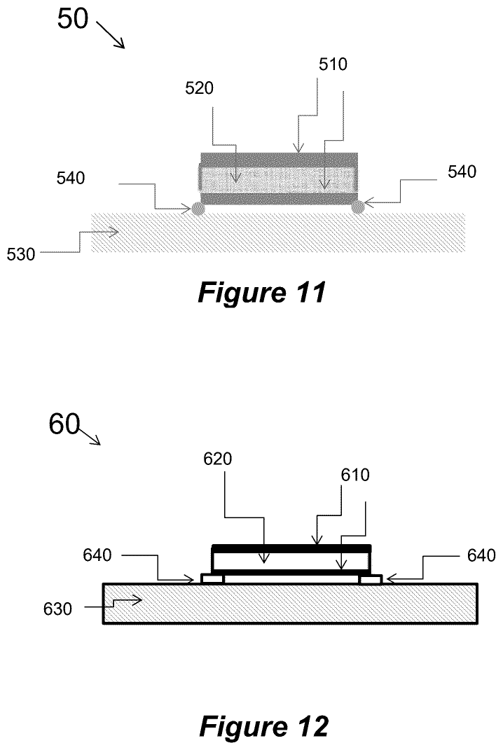

To enhance the reliability and long-term performance of microelectronic packaging with high-functioning getter-based scavenging solutions, a heat spot welding method can be used to install a getter metal foil inside the package. FIG. 11 shows cross-sectional views of a getter assembly 50 installed onto a package lid surface 530 via heat spot welding at edges or corners of the getter assembly. This method secures the Pd-gas adsorption layer 510 and Ti-gettering layer 520 within the package at least by four heat spot welding points 540, ensuring effective absorption of residual gases and maintenance of the desired vacuum or inert atmosphere within the electronics package.

Another method of the getter installation in a package involves using low-outgassing adhesive for attachment. FIG. 12 shows cross-sectional views of a getter assembly 60 affixed to a package lid surface or interior wall 630, even near components with higher H₂ outgassing, using such adhesive. The adhesive secures the Pd-gas adsorption layer 610 and Ti-gettering layer 620 within the package 60 with at least four attachment patches 640. Using adhesives with low outgassing is essential to prevent contamination within the sealed electronics package. Adhesives like RTV 566, RTV 567, or RTV 577LV are chosen for their stability and minimal outgassing properties. While this method effectively bonds the getter foil within the package, it is limited to temperatures below 250° C. due to the adhesive's constraints. Alternative adhesives may be considered if their outgassing does not adversely affect the performance of the electronic components inside the package.

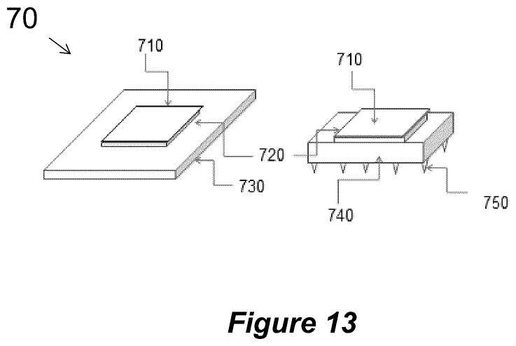

FIG. 13 illustrates the installation of a getter assembly 70 using a pin grid array (PGA) or land grid array (LGA) socket 730, or an IC socket 740, which can be simply inserted into a printed circuit board without electrically connected pins 750. The getter assembly features an outer gas adsorption layer 710 and an internal getter layer 720. The substrate may be made of ceramic or glass-based dielectric material. PGA or LGA sockets 730 accommodate the specific shape and size of the ceramic or glass substrate getter, with a locking mechanism to secure it in place. In addition to high-outgassing microelectronics, electronics, and industrial electronics systems, semi-hermetic polymer-based electronics packages frequently face reduced operational lifespans due to the release of chemical contaminants, including hydrogen.

A getter assembly can capture and contain hydrogen, preventing its buildup in the package headspace, which could otherwise cause corrosion, alterations in electrical properties, and diminished insulation. These contaminants can progressively impair the performance and reliability of electronic components. Historically, low-capacity hydrogen getters (fewer than 100 cc) have been considered impractical. However, installing a getter assembly in a PGA/LGA 730 socket or IC 740 socket can efficiently remove hydrogen and other contaminants especially from the polymer-based package, thereby prolonging the polymer package's operational lifespan and improving its reliability, even in semi-hermetic sealing. Moreover, the getter assembly's lack of need for thermal activation and regeneration makes it especially suitable for various outgassing and scavenging applications from any kinds of devices, modules, packages, and enclosures, given its wide operational temperature range from cryogenic conditions as low as −162° C. to temperatures as high as 200-300° C.

Another key advantage of the Pd-plated Ti foil-based hydrogen getter assembly is its exceptional performance across a broad range of operating temperatures and hydrogen scavenging capacities. This design synergistically combines palladium's excellent hydrogen absorption capabilities with titanium's high thermal stability. The titanium foil provides structural support and maintains integrity under high temperatures, while the palladium layers efficiently trap hydrogen. The triple-layered and bi-layered structures not only enhance the surface area for hydrogen absorption but also distribute thermal stresses, ensuring effectiveness across a wide temperature range without cracking and delamination. This multilayer design allows for increased hydrogen scavenging volumes, making it suitable for scavenging highly outgassed hydrogen from a variety of electronics packages and industrial electronics systems.

What is the claimed is:

1. A getter assembly for scavenging outgassed hydrogen from an electronics package, or industrial electronics system enclosure, or/and semi-hermetic polymer electronics packages, comprising:
an adsorption layer;
a gettering layer;
a substrate.

2. The getter assembly of claim 1, wherein the getter assembly comprises a triple-layered structure, with the gettering layer sandwiched between two gas adsorption layers.

3. The getter assembly of claim 1, wherein the gas adsorption layer is composed of palladium or 5-15 wt. % metal-doped nickel, silver, and gold alloys, with a grain size ranging from 20 to 50 nm and with a thickness ranging from 0.1 μm to 5 μm.

4. The getter assembly of claim 1, wherein the gettering layer is made from rolling mill titanium foil containing micrometer particles with grain sizes ranging from 5 μm to 20 μm and with a thickness from 0.1 mm to a few millimeters.

5. The getter assembly of claim 4, wherein the gettering layer is made from rolling mill pure titanium foil, including Grade 2, Grade 4 and Grade 5 titanium foil or sheet with grain sizes ranging from 5 μm to 20 μm and with a thickness from 0.1 mm to a few millimeters.

6. The getter assembly of claim 2, wherein the two interfaces between the getter layer and the gas adsorption layers feature both nano-scale and micro-scale grain morphologies, symmetrically positioned on the top and bottom surfaces of the gettering layer.

7. The getter assembly of claim 1, wherein the substrate is an electrically conductive Kovar, Alloy 52, or aluminum-alloy foil or sheet, and wherein the substrate may be an electrically insulating material: alumina ceramic, borosilicate glass, or a glass with a smaller thermal expansion mismatch with Ti gettering layer with a thickness ranging from 0.10 mm to 1.00 mm.

8. The getter assembly of claim 1, wherein the assembly can be installed in an electronics package using either heat spot welding or low-outgassing adhesives like RTV 566, RTV 567, and RTV 577LV. It may be attached to the internal surface of a package lid, the interior wall of the package, or within a large electronics enclosure.

9. The getter assembly of claim 1, wherein the getter assembly may be operable from cryogenic −162° C. to 200-300° C. with a thickness of the gettering layer from 001.mm to 0.10 mm for hydrogen removal from microelectronics and electronics packages with package volume less than 100 cc.

10. The getter assembly of claim 1, wherein the getter assembly may be operable from −55° C. to 125-150° C. with a thickness of the gettering layer from 0.10 mm to a few millimeters for highly hydrogen outgassing removal from various industrial electronics systems and semi-hermetic polymer electronic packages with package volume greater than 100 cc or 1000 cc.

11. A method of fabricating a getter assembly, comprising:
Material preparation;
Oxide removal;
Acid pickling;
Surface activation;
Layer plating;
Bakeout process; and
Thermal post-treatment process.

12. The method of claim 11, wherein the material preparation process involves cleaning the gettering material foil with an alkaline cleaner or degreaser to remove oils, greases, and other contaminants, followed by a thorough rinse with deionized water.

13. The method of claim 11, wherein the oxide layer is removed from rolling mill titanium foil surfaces using an acid etching solution consisting of a dilute solution of hydrofluoric acid (HF) or a mixture of hydrochloric acid (HCl) and nitric acid (HNO₃), with a specific etching solution comprising 10-15% HF, 30-45% HNO₃, and 40-60% water.

14. The method of claim 11, wherein the acid pickling process involves submerging the titanium foil in the etching solution for several minutes to an hour to remove the oxide layer, followed by thorough rinsing with clean water.

15. The method of claim 11, wherein the surface activation process includes dipping the cleaned titanium foil in a sensitizing solution containing stannous chloride (SnCl₂) for 1-2 minutes, followed by immersion in an activation solution containing palladium chloride (PdCl₂) for 1-2 minutes, and then thoroughly rinsing with deionized water.

16. The method of claim 11, wherein the layer plating process involves preparing a plating bath at a temperature of 50° C. to 70° C. and adjusting the bath pH to 8-10, with the preferred bath temperature being close to the getter assembly's operating temperature to reduce interface stress around the operating temperature.

17. The method of claim 11, wherein the bakeout process involves heating the plated getter assemblies to a temperature of 150° C.-200° C. for a dwell time of 1-4 hours in a vacuum furnace to remove hydrogen outgassing from the plated assemblies.

18. The method of claim 11, wherein the thermal post-treatment process involves heating the getter assembly at temperatures of 200° C.-400° C. for a duration ranging from a few hours to 48 hours to relieve interface stresses, enhance ductility, and improve bond strength at the interface from a vacuum furnace.

19. The method of claim 11, wherein the thermal post-treatment process in an oxygen-rich, benchtop oven, environment forms a TiO₂ thin film on freshly cut small pieces of the getter assembly, acting as a barrier to protect the integrity of the gettering layer.
